(19) United States
(12) Patent Application Publication
(10) Pub. No.: US 2007/0283885 A1
(43) Pub. Date: Dec. 13, 2007

(54) DEVICE FOR VAPORIZING MATERIALS WITH A VAPORIZER TUBE

(75) Inventor: Guido Hattendorf, Brachttal (DE)

Correspondence Address: FISH & RICHARDSON P.C., PO BOX 1022, MINNEAPOLIS, MN, 55440-1022, US

(73) Assignee: APPLIED MATERIALS GMBH & CO. KG, Alzenau (DE)

(21) Appl. No.: 11/757,291

(22) Filed: Jun. 1, 2007

(30) Foreign Application Priority Data
Jun. 3, 2006 (EP) 06011585.4

(51) Int. Cl. C23C 16/04

(52) U.S. Cl. 118/716

(57) ABSTRACT

The invention relates to a device for the vaporization of materials with a vaporizer tube or the like, which includes at least one discharge port for the vaporized material. The vaporizer tube is connected with a vapor distributor and comprises at least two separately heatable vaporizer units. In the vaporizer tube are provided an upper and a lower piston, which are separated by a gap. The at least two separate vaporizer units encompass at least the lower and/or the upper piston in the form of tongs.

### TECHNICAL FIELD

A device for vaporizing materials is described.

### BACKGROUND

The electronic device industry can today no longer be imagined without coating processes for the application of layers on substrates as a fabrication technique. The layers applied on these substrates can serve for example as protective layers or only as decorative layers.

An example of such a coating process is the vaporization process. In a vaporization process materials are introduced into a vaporizer device and subsequently converted to the gaseous phase. These gaseous materials subsequently move in the direction toward a substrate where they are deposited and form a highly uniform layer. It is understood that after such a first layer has been applied, further layers can be applied in this manner such that it is also possible to apply multilayer systems onto a substrate.

For example, a coating process is known in which a substrate is coated in a vacuum chamber with vaporous organic material (EP 1 401 036 A2). The coating chamber includes several vaporizer sources, disposed one next to the other, which are connected with a vapor outlet provided with nozzles, via which the vapor can migrate in the direction toward the substrate in order to be deposited thereon. Between each vaporizer source and the vapor outlet a valve is provided with which the quantity of the outflowing vapor can be adjusted.

A vaporizer device for coating a substrate is furthermore known, which includes a coating chamber (US 2005/0241585 A1). This vaporizer device further comprises at least two vaporizer sources disposed separately from one another, which include means with which the quantity of vapor flowing into the coating chamber can be individually controlled.

A vaporizer device is further known with several vaporizer sources (U.S. Pat. No. 6,770, 562 B2) placed separately next to one another. Above these vaporizer sources is located a coating chamber in which the substrate is disposed. The coating chamber is partitioned into several sections through which the substrate passes successively. Each of these sections is connected to one vaporizer source each, such that the substrate is coated successively by the vapor leaving the vaporizer sources. A valve disposed between the sections and the vaporizer sources serves for controlling the quantity of outflowing vapor.

### SUMMARY

In one aspect, a device for vaporizing materials is described. The device includes a vaporizer tube or the like, which includes at least one discharge port for the vaporized material. The vaporizer tube is connected with a vapor distributor and comprises at least two separately heatable vaporizer units. In the vaporizer tube are provided an upper and a lower piston separated by a gap. The at least two separate vaporizer units encompass at least partially the lower and/or the upper piston in the form of tongs.

One potential advantage is reducing the thermal loading of the material to be vaporized in spite of a long service life of the device for the vaporization of material.

Another potential advantage is that materials which do not remain thermally stable over a relatively long time period can also be vaporized. The material is for this purpose can be vaporized in small portions. Additional material can be only made available when the previous portion has been vaporized. The material to be vaporized can thereby only be exposed to the vaporization temperature for a short time.

Another potential advantage is that the adjacent vaporizers can be driven steplessly, whereby the vaporization can run continuously without interruption.

### DESCRIPTION OF DRAWINGS

FIG. 1 a segment of a device for vaporizing material with a vaporizer tube located outside of the vacuum chamber,

FIG. 2 a segment of the vaporizer tube depicted in FIG. 1 according to section along B-B and C-C through this vaporizer tube,

FIG. 3 a perspective view of a vaporizer unit,

FIG. 4 a top view onto the segment of the vaporizer tube depicted in FIG. 2,

FIG. 5 a section through the segment of the vaporizer tube depicted in FIG. 2 along D-D,

FIG. 6 a partial segment of the vaporizer tube depicted in FIG. 5 after the section has also been carried out through the vaporizer units.

### DETAILED DESCRIPTION

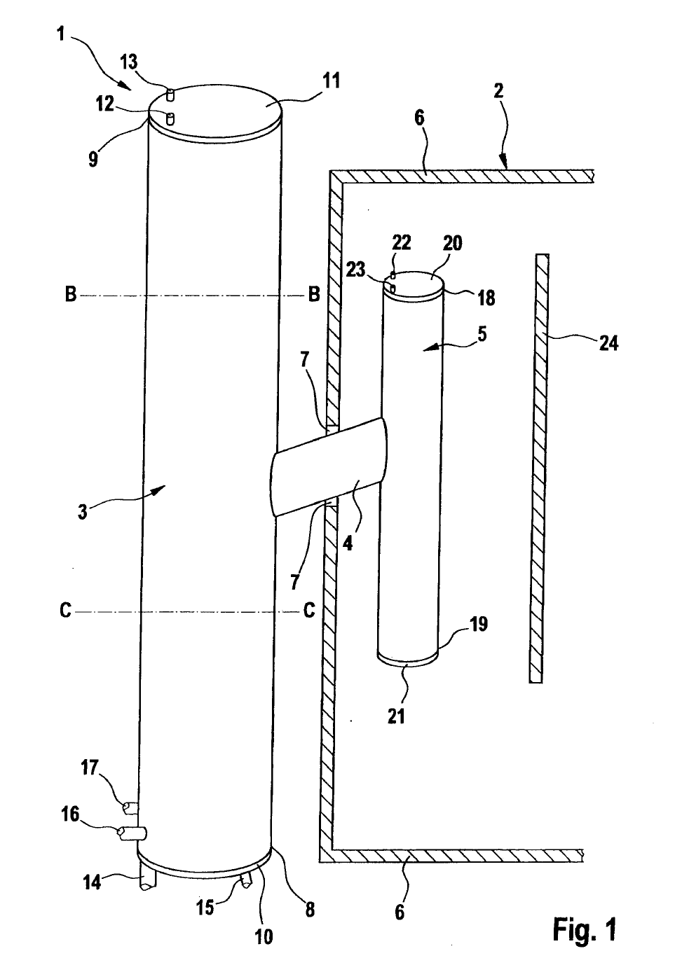

FIG. 1 depicts a segment of a device 1 for the vaporization of material with a vaporizer tube 3 located outside a vacuum chamber 2. This vaporizer tube 3 is connected via a connection tube 4 with a distributor 5 disposed within the vacuum chamber 2. For the sake of clarity, only a segment of the vacuum chamber 2 with the vacuum chamber wall 6 is shown, the vacuum chamber 2 being structured, for example, corresponding to the vacuum chamber described in DE 101 28 091 C1.

In order for a pressure to be maintained once it is established in the vacuum chamber 2, the vacuum chamber wall 6 completely encompasses the connection tube 4. However, it is also possible that, as also depicted in FIG. 1, sealing material 7 is additionally applied around the connection tube 4. Thereby the pressure obtained in the vacuum chamber 2 can be maintained. The sealing material 7 includes, for example, a rubber-type elastic material impermeable to gas.

The vaporizer tube 3 is sealed off at both ends 8, 9 with closures 10, 11, for example with caps 10, 11. These caps 10, 11 preferably include at least one connection. Thus cap 11, as shown in FIG. 1, includes two connections 12, 13. To one of these connections 12, for example, a heater can be connected which, however, is not shown here. With this heater the material in the vaporizer tube can be vaporized. To the other connection 13 can be attached a temperature sensor, with which the temperature conditions occurring in the vaporizer tube 3 can be monitored. The temperature sensor is, however, not shown here.

Slots can be provided in the vaporizer tube 3 for the connections of the heating and the cooling systems of the vaporizer units. The connections at the vaporizer units can be effected as rigid connections, and the external supply lines can be effected as flexible.

The cap 10 also includes several connections 14, 15. Via the connection 14, the vaporizer tube 3 is connected with a control. At the connection 15 a vacuum pump may be attached with which a vacuum can be generated in the vaporizer tube 3 such that, before the vaporization process, a pressure can be obtained which corresponds to that in the vacuum chamber 2. A vacuum pump, however, is not shown for the sake of clarity.

The vaporizer tube 3 may also include several connections. Thus, in FIG. 1 two connections 16, 17 are evident which are disposed directly on the vaporizer tube 3. These connections 16, 17 serve the purpose of providing the vaporizer tube 3 with a coolant, for example water, when needed. The connection 16 serves herein for example as coolant outlet and connection 17 as coolant inlet.

Like the vaporizer tube 3, the distributor 5 is also closed at its two ends 18, 19. This can be accomplished for example with closures 20, 21, for example caps 20, 21. These caps 20, 21 can also be provided with connections, only two connections 22, 23 being shown in FIG. 1, which are disposed on cap 20. Via these connections 22, 23 the distributor 5 can, for example, be connected with a heater, such that in the distributor 5 a temperature is obtained, for example, which corresponds to the temperature obtained in the vaporizer tube 3. However, the connections 22, 23 may also be utilized for the coolant supply or for applying a temperature sensor. Heater, temperature sensor or coolant supply are not shown in FIG. 1.

The distributor 5 includes at least one opening, preferably several openings disposed in a row, which, however, are not evident in FIG. 1. Through these openings the vapor reaches the substrate 24 located in the vacuum chamber 2. This substrate 24 is moved past the at least one opening of the distributor, such that the vapor moves toward the substrate 24 and is here deposited. The substrate shown in FIG. 1 is therein moved into or also out of the plane of drawing. Such a movement of the substrate past the distributor is described for example in DE 101 28 091 C1, the disclosure of which is incorporated by reference.

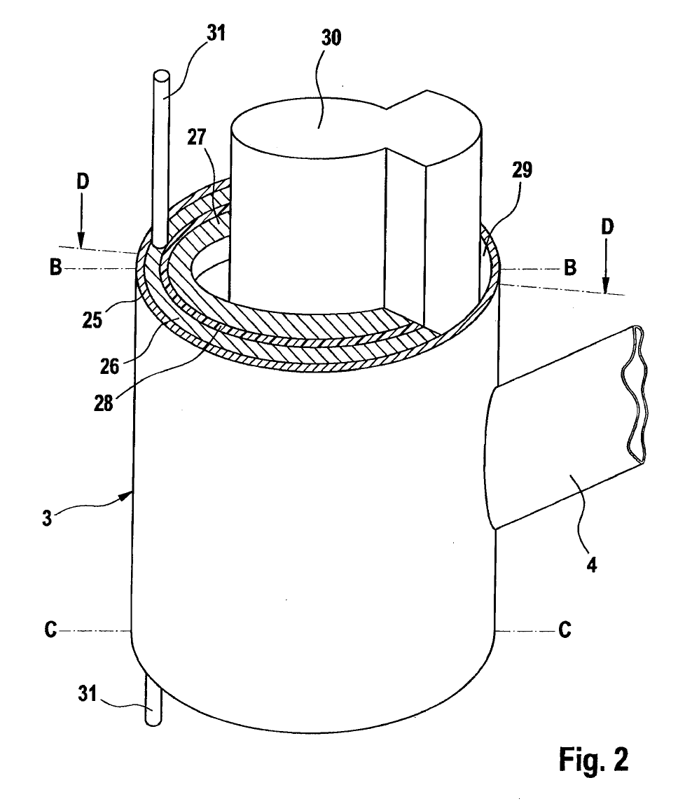

FIG. 2 shows a segment of the vaporizer tube 3 depicted in FIG. 1 after section through this vaporizer tube 3 along B-B and C-C. In the interior of the vaporizer tube 3 with its wall 25 is disposed a cylinder 26 which is directly in contact on the wall 25. A vaporizer unit 27 in the form of a ring is disposed on the cylinder 26, and between this vaporizer unit 27 and the cylinder 26 is located an insulating layer 28. The vaporizer unit 27, the cylinder 26 as well as the insulating layer 28 are open in a region 29 in the direction toward the connection tube 4.

Through the vaporizer unit 27, as well as the region 29 open in the direction toward the connection tube 4, extends an inner piston, which is divided into an upper and a lower piston. Only the upper piston 30 is evident in FIG. 2. In contrast to the upper piston 30, cylinder 26 with the insulating layer 28 as well as the vaporizer unit 27 are not fixedly disposed in the vaporizer tube 3, but are movable along a guide rod 31. The movement is therein controlled via the control connected to the connection 14 (FIG. 1).

Since the vaporizer unit 27 is disposed directly on the upper piston 30, the upper piston 30 also serves as a guide element. The disposition comprised of vaporizer unit 27, cylinder 26 as well as insulating layer 28 can consequently be moved along the upper piston 30.

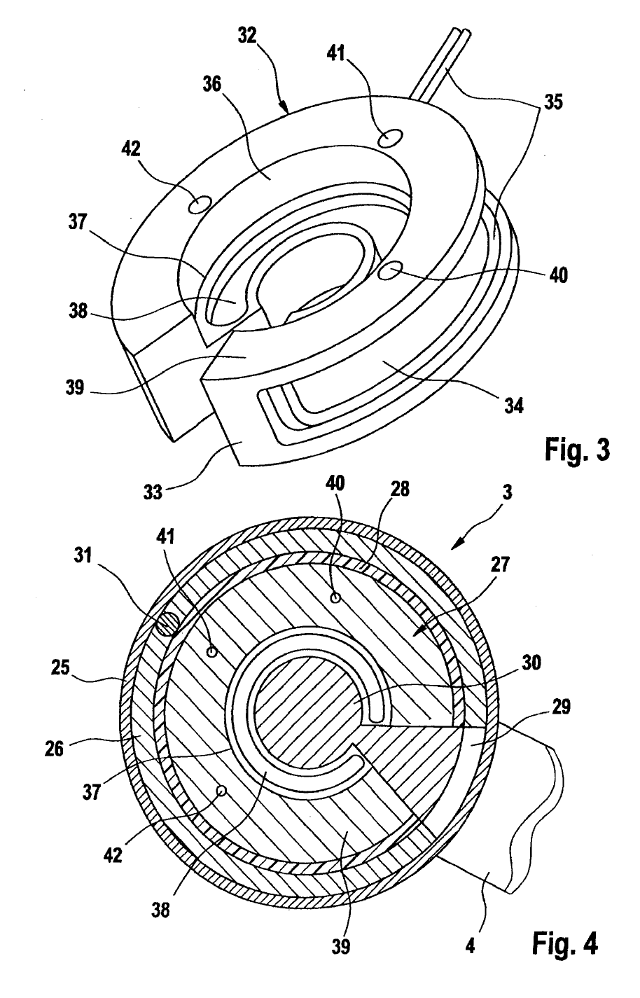

FIG. 3 shows a perspective view of a vaporizer unit 32, which corresponds to the vaporizer unit 27, without showing the insulating layer 28 encompassing it and without the cylinder 26. The vaporizer unit 32, which has the form of a ring open toward one side, includes on the outside 33 an indentation 34, in which an encircling heater 35 is disposed. This heater 35 may be for example a heating filament.

However, it is also conceivable that a heating filament is disposed in the interior of the vaporizer unit 32 and that a cooling system is located in the indentation 34. As the cooling means can serve water, which, it is understood, must be removed during heating operation. The vaporizer unit includes at its internal side 36 a tub 37 for receiving the material 38 to be vaporized and with which the substrate is to be coated. The vaporizer unit 32 further comprises at its top side 39 three openings 40, 41, 42. Since the vaporizer unit 32 is preferably comprised of a material which has good thermal conductivity, via the heater 35 consequently the entire vaporizer unit 32 is brought to a temperature at which the material 38 to be vaporized is converted into the gaseous state.

FIG. 4 depicts a top view onto the segment shown in FIG. 2 of the vaporizer tube 3. Evident are the wall 25 of the vaporizer tube 3 as well as the cylinder 26 disposed thereon with the insulating layer 28 and the vaporizer unit 27. The vaporizer unit 27 includes on its top side 39 several openings 40 to 42. These openings 40 to 42 serve for fixing the insulating layer 50, 71 to 79 of the vaporizer units on one another by means of rods. These vaporizer units could become turned out of position as soon as they are in operation and the pistons 30, 80 are not available as guides.

Evident is also the tub 37 of vaporizer unit 27, in which is located the material 38 to be vaporized. The vaporizer unit, open in the direction toward region 29, encompasses the upper piston 30. Along the guide rod 31 it is possible to move the vaporizer unit 27 disposed on cylinder 26 with the insulating layer 28 along the upper piston 30. The upper piston 30 consequently serves as a guide element.

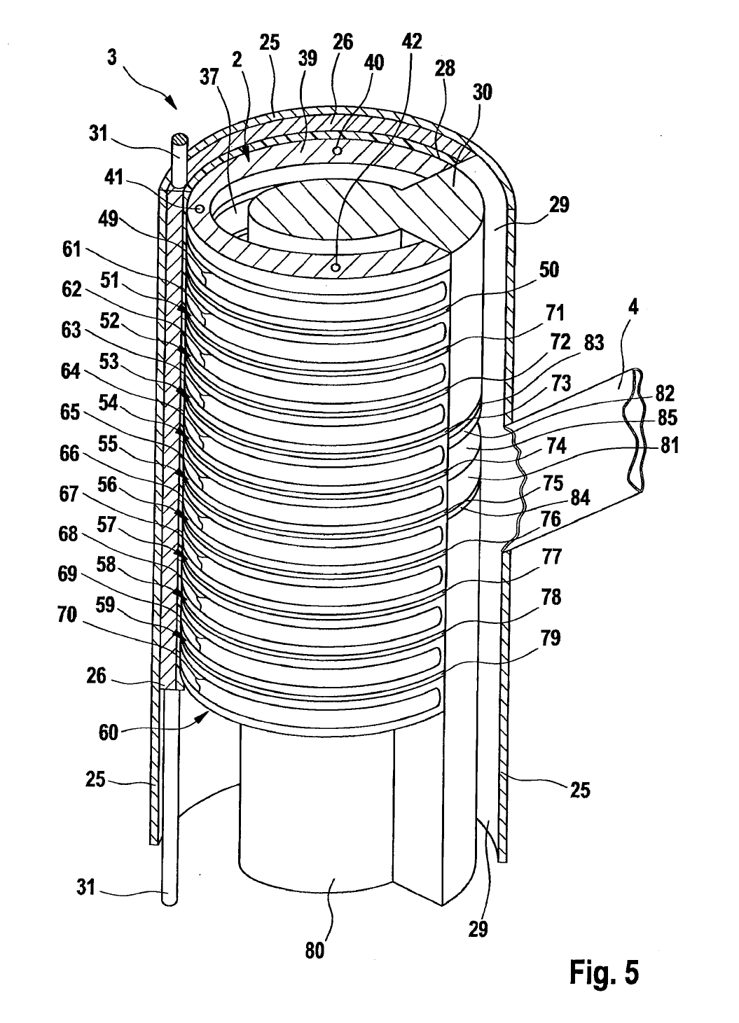

FIG. 5 shows a section through the segment depicted in FIG. 2, of the vaporizer tube 3 along D-D, the section only being completed through wall 25, cylinder 26 as well as the insulating layer 28. The section is not carried out through the vaporizer units 27, 51 to 60. Visible is the wall 25 of vaporizer tube 3. On the inside of wall 25 rests the cylinder 26 with the insulating layer 28. The cylinder 26 is therein disposed on the guide rod 31.

On the insulating layer 28 vaporizer units 27, 51 to 60 are directly disposed, each of which includes heating elements 49, 61 to 70, which are applied on the outer sides of 27, 51 to 60. Between each of the vaporizer units 27, 51 to 60 is placed in each instance one insulating layer 50, 71 to 79.

Each vaporizer unit 27, 51 to 60 comprises a tub in which is located the material to be vaporized. However, only tub 37 of vaporizer unit 27 can be seen, in which the material 38 to be vaporized is made available. The vaporizer units 27, 51 to 60 are in contact on the upper piston 30 and on the lower piston 80. Both pistons 30, 80 serve as guide elements for the vaporizer units 27, 51 to 60. Cylinder 25 can consequently be moved together with the vaporizer units 27, 51 to 60 along the guide rod 31 either in the direction of the upper piston 30 or the lower piston 80.

The upper and lower piston 30, 80 are each provided with a heater 81, 82, which are separated from the upper or the lower piston 30, 80 through an insulation 83, 84. Between the heater 82 of the upper piston 30 and the heater 81 of the lower piston 80 can be seen a gap 85 through which the vaporized material reaches via the open region 29 the connection tube 4, and lastly via the distributor 5—as shown in FIG. 1—arrives on the substrate 24.

The lower piston 80 and the heater 81 disposed thereon can be moved back and forth in the direction of the upper piston 30 so that the size of the gap 85 can be varied.

The vaporizer units are disposed parallel one above the other and are displaceable relative to one another along an imaginary common axis.

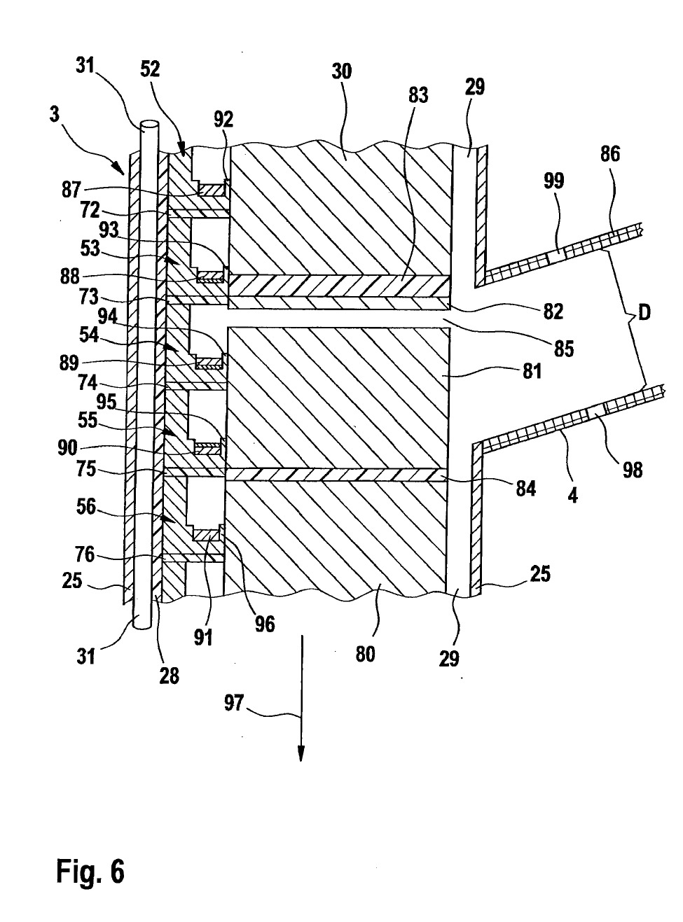

In FIG. 6 is shown a partial segment of the vaporizer tube 3 depicted in FIG. 5, with its wall 25 as well as the connection tube 4 with its wall 86, the section also being carried out through the vaporizer units 27, 51 to 60. Evident are only the vaporizer units 52 to 56. The cylinder 26 extends through the guide rod 31 such that in FIG. 6 the cylinder 26 is not visible.

On guide rod 31 are disposed the insulating layer 28 and directly thereon the vaporizer units 52 to 56. The vaporizer units 52 to 56 disposed on the cylinder 26 can thus be moved in the direction of the upper piston 30 or of the lower piston 80. Each of the vaporizer units 52 to 56 include tubs 92 to 96, in which is the material 87 to 91 to be vaporized.

Although the vaporizer units 52 to 56 have been referred to as rings with tubs 92 to 96, these vaporizer units 52 to 56 can also have a different shape. It is only important that these in that case also have a facility for receiving the material to be vaporized as well as include a heater.

Since the vaporizer units 52 to 56 are each provided with a heater as well as possibly a cooling device, and thereby that the vaporizer units 52 to 56 are separated through insulating layer 72 to 76 from one another, each vaporizer unit 52 to 56 can be heated separately. In this way it is possible to vaporize only the material 89 located in the tub 94 of the vaporizer unit 54. This vaporized material subsequently reaches through the gap 85 into region 29. From this region 29 the vapor can lastly migrate through the distributor 5 (FIG. 1) in the direction toward substrate 24. The heaters 81, 82 of the upper piston 30 and of the lower piston 80 prevent the vapor from already condensing there on these pistons.

Although not shown, it is understood that the connection tube 4 can also be equipped with heating elements in order to prevent there the condensation of the vapor.

The vaporizer units 52 to 56 can be directly in contact on the upper or lower piston 30, 80 and insulating material can be disposed between the vaporizer units, so that the vapor can only escape through the gap 85 in the direction of the connection tube 4.

If not only the material 89 is to be vaporized from the tub 94 of the vaporizer unit 54, the lower piston 80 can be moved in the direction of arrow 97, such that the gap 85 is enlarged. If the lower piston 80 is moved for example by a length D in the direction of arrow 97, with D corresponding to the inner diameter of the connection tube 4, the material 90 of the vaporizer unit 55 can also escape from the gap now enlarged by D. It is advantageous for each vaporizer unit 52 to 56 to include its own heater. Thus, the vaporizer units can be heated individually, and specifically only those vaporizer units which are in the proximity of gap 86.

Consequently, the entire material located in the vaporizer tube 3 need not be heated, but only the material in those vaporizer units which are directly located on the gap. In addition, the material is available in portions and is therefore also only heated in portions. This has the advantage that material which cannot withstand long thermal loading, and consequently breaks down due to this loading, is only exposed to high temperature for a short time.

As is evident in FIG. 6, it is possible that only the material 89 in tub 94 of the vaporizer unit 54 is vaporized. When the material 89 has been vaporized, another vaporizer unit, in which there is still material, is moved into the position of the vaporizer unit 54 and the material located in this vaporizer unit is vaporized.

It is advantageous not to wait until the material 89 from vaporizer unit 54 has been completely vaporized. In order to ensure a continuous process with constant vaporizer rate, a measuring instrument is preferably utilized with which the vaporization rate can be determined.

It is for example possible to determine through IR measurement the concentration of the vaporized material by having the connection tube 4 serve as a measuring cell, wherein the connection tube 4 comprises two opposing windows 98, 99 through which IR light radiation is transmitted. Utilizing the mathematical method of chemometry, the concentration of the vaporous material can subsequently be determined.

If the concentration falls below a certain value, another vaporizer unit is brought into the position of the vaporizer unit 54 and the material located in this vaporizer unit is vaporized.

If the vaporizer rate is to be increased, this is possible, for one, by raising the vaporization temperature and, for another, by enlarging the gap 85. By enlarging gap 85 additional vaporizer units are located in the proximity of gap 85, whereby the material located in these vaporizer units can also be vaporized. Depending on the size of the gap, a different number of vaporizer units are also selected and therewith also the quantity of material to be vaporized, whereby a finely graduated rate regulation is possible.

Due to these vaporizer units with only a certain quantity of material, it is not necessary to vaporize the entire material located in the vaporizer tube 3. Thus the portioned quantities of material in the particular vaporizer units are only exposed to the high temperatures for a relatively short time, whereby the material is vaporized before is can break down due to the thermal loading.

Through the large number of vaporizer units which can be brought into the position correct for the vaporization of material via the guide element, material can be continuously made available to the vaporization process. As a result a constant vaporization rate can be continuously ensured. The service life of the total installation is accordingly also long enough in order to be able to coat large areas also.

In principle, two movements, independently of one another, relative to the vaporizer tube 3 fixed on the installation must be differentiated.

In the one movement, which relates to the piston 30 or the piston 80, one of the two pistons is fixed on the vaporizer tube 3. The other piston is for example driven via a vacuum-tight linear slide guide from outside of the vacuum. Which of the two pistons 30, 80 is fixed and which is movable does not affect the function.

The other movement, regarding the movement of the vaporizer units, can also take place via vacuum-tight slide guides which are driven from outside of the vacuum. The vaporizer units are connected with rods in openings 40 to 42 to form a unit, including the insulations.

Various embodiments have been described. Nevertheless, it will be understood that various modifications may be made without departing from the spirit and scope of the invention. Accordingly, other embodiments are within the scope of the following claims.

What is claimed is:

1. A device for the vaporization of materials, comprising:
a vaporizer tube which includes
at least one discharge for the vaporized material, and
at least two vaporizer units disposed in parallel and movable along a common axis relative to one another.

2. The device of claim 1, wherein each of the vaporizer units includes a separate heater.

3. The device of claim 1, further comprising guide elements for the vaporizer units, wherein at least one guide element is displaceable.

4. The device of claim 3, wherein the guide elements are pistons which are at least partially encompassed by the vaporizer units in the form of tongs.

5. The device of claim 1, wherein the vaporizer units are disposed on a cylinder which is in contact with an internal side of a wall of the vaporizer tube.

6. The device of claim 5, wherein the cylinder is disposed on a guide rod.

7. The device of claim 5, wherein insulation material is disposed between the cylinder and the vaporizer units.

8. The device of claim 1, wherein insulation material is disposed between the vaporizer units.

9. The device of claim 1, wherein each of the vaporizer units includes receiving area for the material to be vaporized.

10. The device of claim 9, wherein each of the vaporizer units includes a separate heater to heat material in the receiving area.

11. The device of claim 1, wherein each of the vaporizer units includes a separate cooling system.

12. The device of claim 1, wherein the vaporizer units are movable along a guide rod.

13. The device of claim 12, wherein the vaporizer units are disposed on a cylinder and the cylinder is disposed on the guide rod.

14. The device of claim 1, wherein the vaporizer units are rings open toward one side.

15. The device of claim 14, wherein the vaporizer units that open toward one side encompass the upper piston or the lower piston in the form of tongs.

16. The device of claim 1, wherein at least one of the vaporizer units is disposed at the level of a gap.

17. The device of claim 16, wherein the gap is formed by a heater disposed on the upper piston and a heater disposed on the lower piston.

18. The device of claim 17, wherein insulation material is disposed between the lower piston and the heater and between the upper piston and the heater.

19. The device of claim 1, further comprising a connection tube disposed between the vaporizer tube and a distributor.
